(19) United States
(12) Patent Application Publication
(10) Pub. No.: US 2020/0408867 A1
(43) Pub. Date: Dec. 31, 2020

(54) CONTROL CIRCUIT AND CALIBRATION SYSTEM

(71) Applicant: NIDEC SERVO CORPORATION, Kiryu-shi (JP)

(72) Inventor: Masatomo Ishikawa, Kiryu-shi (JP)

(21) Appl. No.: 16/911,435

(22) Filed: Jun. 25, 2020

(30) Foreign Application Priority Data
Jun. 26, 2019 (JP) 2019-118713

(51) Int. Cl. G01R 35/00; H02P 29/00

(52) U.S. Cl. CPC G01R 35/005; H02P 29/00

(57) ABSTRACT

A control device includes a control circuit that controls a target device, the control circuit including a controller that controls a calibration circuit to be connected to the control circuit, in which the controller calibrates the control circuit by controlling the calibration circuit when a predetermined condition is satisfied in a state where the control circuit is connected to the calibration circuit.

### CROSS REFERENCE TO RELATED APPLICATION

The present application claims priority under 35 U.S.C. § 119 to Japanese Application No. 2019-118713 filed on Jun. 26, 2019, the entire contents of which are hereby incorporated herein by reference.

### FIELD OF THE INVENTION

The present disclosure relates to a control circuit and a calibration system.

### BACKGROUND

Research and development on calibration of a control circuit that controls a target device has been conducted. The calibration of the control circuit includes, for example, calibrations of a clock, a voltage sensor, a current sensor, included in the control circuit.

Calibration of the control circuit is performed in order to reduce individual differences among manufactured control circuits. However, calibrating each control circuit increases the number of work steps in the process of manufacturing control circuits, and may increase the manufacturing cost of control circuits. The individual differences among control circuits can also be reduced by reducing individual differences among individual components constituting the control circuits. However, reducing the individual differences among individual components means using components having less variation in characteristics (that is, high-precision components) as the individual components. Components having less variation in characteristics tend to be more expensive than components having great variation in characteristics. As a result, reducing the individual differences among individual components may also increase the manufacturing cost of control circuits.

Under the circumstances described above, it has conventionally been difficult to reduce individual differences among control circuits without increasing manufacturing cost.

### SUMMARY

An example embodiment of the present disclosure provides a control circuit that controls a target device, the control circuit including a controller that controls a calibration circuit to be connected to the control circuit, in which the controller calibrates the control circuit by controlling the calibration circuit when a predetermined condition is satisfied in a state where the control circuit is connected to the calibration circuit.

Another example embodiment of the present disclosure provides a control circuit that controls a device to be controlled, the control circuit including a controller that controls a calibration circuit to be connected to the control circuit, in which the controller calibrates the control circuit by controlling the calibration circuit when a predetermined condition is satisfied in a state where the control circuit is connected to the calibration circuit, and when the controller does not calibrate the control circuit, the controller does not control the device.

An additional example embodiment of the present disclosure provides a calibration system including the control circuit and the calibration circuit described above.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a diagram showing an example of a configuration of a calibration system 1 according to an example embodiment of the present disclosure.

FIG. 2 is a diagram showing an example embodiment of a processing routine of a process performed by a control circuit 11 to calibrate the control circuit 11 using a calibration circuit 12.

FIG. 3 is a diagram showing an example embodiment of a circuit configuration of a clock calibration circuit 121.

FIG. 4 is a diagram showing a circuit configuration of a voltage sensor 114 and a circuit configuration of a voltage sensor calibration circuit 122 according to an example embodiment of the present disclosure.

FIG. 5 is a diagram showing a circuit configuration of a current sensor 115 and a circuit configuration of a current sensor calibration circuit 123 according to an example embodiment of the present disclosure.

FIG. 6 is a diagram showing an example embodiment of a graph obtained by plotting the correspondence between a first current value and a second current value.

FIG. 7 is a diagram showing an example embodiment of a processing routine of a process performed by the control circuit 11 for correcting a first clock frequency.

FIG. 8 is a diagram showing an example embodiment of a processing routine of a process performed by the control circuit 11 for correcting a voltage value of a voltage detected by the voltage sensor 114.

FIG. 9 is a diagram showing an example embodiment of a processing routine of a process performed by the control circuit 11 for correcting a current value of a current detected by the current sensor 115.

FIG. 10 is a diagram showing an example embodiment of a relationship between a torque target value of a motor M and a rotation speed error rate.

FIG. 11 is a diagram showing an example embodiment of a relationship between a torque target value of the motor M and a variation in rotation speed.

FIG. 12 is a diagram showing an example embodiment of a histogram representing a relationship between a voltage value of a voltage detected when a power-supply voltage VM is detected by a plurality of control circuits 11 and the number of control circuits 11 that have detected each of the voltage values.

FIG. 13 is a diagram showing, when a bus current is detected by a plurality of control circuits 11, a histogram indicating a relationship between the current value of the detected current and the number of control circuits 11 that have detected each current value according to an example embodiment of the present disclosure.

FIG. 14 is a diagram showing a variation in rotation speed of the motor M and a variation in air volume due to a difference in control circuits 11, when same motor M is controlled by a plurality of control circuits 11 according to an example embodiment of the present disclosure.

### DETAILED DESCRIPTION

Example embodiments of the present disclosure will be described below with reference to the drawings.

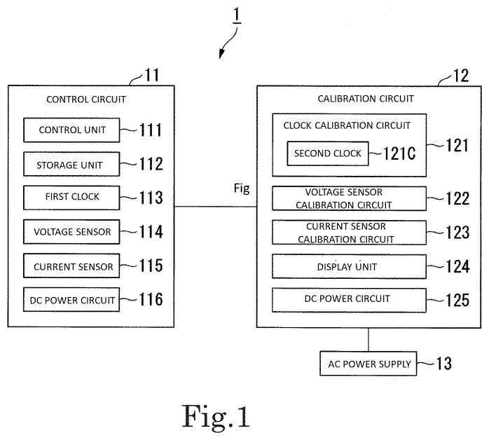

First, a configuration of a calibration system 1 according to an example embodiment will be described with reference to FIG. 1. FIG. 1 is a diagram showing an example of a configuration of the calibration system 1 according to the example embodiment.

The calibration system 1 includes a control circuit 11 and a calibration circuit 12.

In the calibration system 1, the control circuit 11 is calibrated using the calibration circuit 12. The calibration of the control circuit 11 includes, for example, calibration of at least one of a clock, a voltage sensor, and a current sensor, included in the control circuit 11. In the following description, a case where the calibration of the control circuit 11 includes calibrations of the clock, the voltage sensor, and the current sensor included in the control circuit 11 will be described as an example. The calibration of the control circuit 11 may include calibration of another device, another circuit, another sensor, etc.

The control circuit 11 is a circuit that controls a target device. The control circuit 11 controls driving of a motor M (not shown), for example, as the target device. The motor M is a motor that rotates a fan F (not shown) for cooling or forcibly circulating air in a freezer showcase, a refrigerator, or the like. Note that the control circuit 11 may be configured to control another device, another circuit, or the like, instead of the motor M. Further, the motor M may be another motor instead of the motor for rotating the fan F.

Here, it is desirable that individual differences among control circuits 11 be small. The individual differences among control circuits 11 can also be reduced by reducing individual differences among individual components constituting control circuits 11. However, reducing the individual differences among individual components means using components having less variation in characteristics (that is, high-precision components) as the individual components. Components having less variation in characteristics tend to be more expensive than components having great variation in characteristics. As a result, reducing the individual differences among individual components may also increase the manufacturing cost of control circuits 11.

On the other hand, individual differences among control circuits 11 can be reduced by calibrating each of the manufactured control circuits 11. However, calibrating each control circuit 11 increases the number of work steps in the process of manufacturing control circuits 11. As a result, calibrating each control circuit 11 may also increase the manufacturing cost of control circuits 11.

In view of this, the control circuit 11 controls the calibration circuit 12 to calibrate itself, when a predetermined condition is satisfied in a state where the control circuit 11 is connected to the calibration circuit 12. Accordingly, a manufacturer of the control circuit 11 can calibrate the control circuit 11 by connecting the control circuit 11 to the calibration circuit 12 so that the condition is satisfied. This means that the number of work steps for calibrating each control circuit 11 can be reduced by using a simple condition as the predetermined condition. For example, the control circuit 11 can be calibrated only by connecting the control circuit 11 to the calibration circuit 12 as a work step necessary for calibrating the control circuit 11. In this case, the condition is, for example, that power is supplied to the control circuit 11 via the calibration circuit 12 connected to the control circuit 11. That is, the manufacturer can calibrate each control circuit 11 while suppressing an increase in the number of work steps related to the production of each control circuit 11. As a result, the control circuit 11 enables reduction in individual differences, while suppressing an increase in manufacturing cost. In other words, the calibration system 1 including the control circuit 11 can reduce individual differences among control circuits 11 while suppressing an increase in the manufacturing cost of control circuits 11.

Hereinafter, the configuration of the calibration system 1 including the control circuit 11 and processes performed by the control circuit 11 for calibrating the control circuit 11 via the calibration circuit 12 will be described in detail. In the following, a state in which the control circuit 11 is connected to the calibration circuit 12 will be simply referred to as a connection state for convenience of description. Further, in the following, a state in which the control circuit 11 is not connected to the calibration circuit 12 will be simply referred to as a non-connection state for convenience of description.

In the example shown in FIG. 1, the control circuit 11 includes a controller 111, a storage unit 112, a first clock 113, a voltage sensor 114, a current sensor 115, and a DC power circuit 116. In this case, in the calibration system 1, calibrations of the first clock 113, the voltage sensor 114, and the current sensor 115 are performed as the calibration of the control circuit 11. The control circuit 11 may include one or more voltage sensors different from the voltage sensor 114. In this case, the calibration of the control circuit 11 may include calibrations of some of or all of the one or more voltage sensors, or may not include calibrations of all of the one or more voltage sensors. The control circuit 11 may include one or more current sensors different from the current sensor 115. In this case, the calibration of the control circuit 11 may include calibrations of some of or all of the one or more current sensors, or may not include calibrations of all of the one or more current sensors.

The controller 111 controls the entire control circuit 11.

Further, the controller 111 controls the motor M when the control circuit 11 is in the non-connection state and the motor M is connected to the control circuit 11.

Further, the controller 111 controls the calibration circuit 12 in the connection state. More specifically, the controller 111 controls the calibration circuit 12 to calibrate the control circuit 11 when a predetermined condition is satisfied in the connection state. For convenience of description, the condition will be described as a calibration start condition in the following description.

The calibration start condition indicates, for example, that power is supplied to the control circuit 11 via the calibration circuit 12 connected to the control circuit 11 as described above. Note that the calibration start condition may be another condition such as switching a switch for starting the control circuit 11 to ON.

The controller 111 is, for example, a CPU (Central Processing Unit). Note that the controller 111 may include a plurality of CPUs. In this case, the control circuit 11 includes each of the plurality of CPUs as processors that implement a part of the functions of the controller 111. Further, the controller 111 may include another processor such as an FPGA (Field Programmable Gate Array) instead of CPU.

The storage unit 112 is a storage device including, for example, a ROM (Read Only Memory), a RAM (Random Access Memory), and a flash memory. The storage unit 112 may be an external storage device connected to the control circuit 11 instead of the storage device built in the control circuit 11.

The first clock 113 generates a first clock signal. The first clock signal is a clock signal having a predetermined first clock frequency as a nominal value of the clock frequency. The clock frequency of the first clock signal generated by the first clock 113 may deviate from the first clock frequency within a range of a tolerance of the clock frequency due to a manufacturing error of the first clock 113. Here, the tolerance is represented by a ratio of a deviation from the first clock frequency which is the nominal value of the clock frequency. For example, when the tolerance is ±2%, the clock frequency may deviate within a range of ±2% of the first clock frequency in a range around the first clock frequency. In the following, such a deviation of the clock frequency from the first clock frequency will be described as a first clock error. In the example embodiment, the first clock error is indicated by a ratio of a deviation from the first clock frequency. The calibration of the first clock 113 includes calculating, as a first correction coefficient, a correction coefficient for bringing the clock frequency of the first clock signal closer to the first clock frequency, and storing first correction coefficient information indicating the calculated first correction coefficient in the storage unit 112. In the following, a case where the tolerance of the clock frequency is ±2% as described above will be described as an example. In this case, the absolute value of the first clock error exceeding 2% means that the first clock 113 is defective.

The voltage sensor 114 detects a power-supply voltage supplied to the motor M by the control circuit 11. For convenience of description, the power-supply voltage is indicated by VM in the following description. The power-supply voltage VM is a voltage generated by the DC power circuit 116 described later. The voltage sensor 114 may be configured to detect another voltage instead of the power-supply voltage VM. When detecting the power-supply voltage VM, the voltage sensor 114 divides the power-supply voltage VM. The resistance value of a resistor used for dividing the power-supply voltage VM may deviate from a nominal value of the resistance value within a range of a tolerance of the resistance value due to a manufacturing error of the resistor. As a result, the voltage sensor 114 may detect the voltage value of the power-supply voltage VM as a voltage value deviated from an actual voltage value. The calibration of the voltage sensor 114 includes calculating, as a second correction coefficient, a correction coefficient for correcting such a deviation of the voltage value of the power-supply voltage VM detected by the voltage sensor 114, and storing second correction coefficient information indicating the calculated second correction coefficient in the storage unit 112.

The current sensor 115 detects a current. The current sensor 115 has a shunt resistor for detecting a current. The resistance value of the shunt resistor may deviate from a nominal value of the resistance value within a range of a tolerance of the resistance value due to a manufacturing error of the shunt resistor. As a result, the current sensor 115 may detect the current value of the current to be detected as a current value that deviates from an actual current value. The calibration of the current sensor 115 includes calculating a correction formula for correcting such a deviation of the current value of the current detected by the current sensor 115, and storing correction formula information indicating the calculated correction formula in the storage unit 112.

The DC power circuit 116 generates a DC voltage of a desired magnitude as the abovementioned power-supply voltage VM on the basis of the DC voltage supplied to the control circuit 11. The DC power circuit 116 is controlled by the controller 111. The DC power circuit 116 is, for example, a DC (Direct Current)/DC converter. The DC power circuit 116 may be configured to generate another voltage in addition to or in place of the power-supply voltage VM.

In the control circuit 11, some or all of the storage unit 112, the first clock 113, the voltage sensor 114, the current sensor 115, and the DC power circuit 116 may be configured as a microcomputer together with the controller 111.

The calibration circuit 12 includes, for example, a clock calibration circuit 121, a voltage sensor calibration circuit 122, a current sensor calibration circuit 123, a display 124, and a DC power circuit 125. The calibration circuit 12 is connected to an AC power supply 13. An AC voltage is supplied to the calibration circuit 12 from the AC power supply 13 connected to the calibration circuit 12. The calibration circuit 12 may include other devices, other circuits, and the like in addition to the clock calibration circuit 121, the voltage sensor calibration circuit 122, the current sensor calibration circuit 123, the display 124, and the DC power circuit 125.

The clock calibration circuit 121 is a circuit controlled by the controller 111 when the first clock 113 is calibrated. The clock calibration circuit 121 includes a second clock 121C, for example, as shown in FIG. 1. Note that the clock calibration circuit 121 may include another device, another circuit, etc. in addition to or instead of the second clock 121C.

The second clock 121C generates a second clock signal. The second clock signal indicates a clock signal having a predetermined second clock frequency as a nominal value of the clock frequency. The clock frequency of the second clock signal generated by the second clock 121C may deviate from the second clock frequency within a range of a tolerance of the clock frequency due to a manufacturing error of the second clock 121C. Here, the tolerance is represented by a ratio of a deviation from the second clock frequency which is a nominal value of the clock frequency. For example, when the tolerance is ±2%, the clock frequency may deviate within a range of ±2% of the second clock frequency in a range around the second clock frequency. In the following, such a deviation of the clock frequency from the second clock frequency will be described as a second clock error. In the example embodiment, the second clock error is indicated by a ratio of a deviation from the second clock frequency.

Here, the second clock signal is a clock signal used for calibrating the first clock 113. For this reason, it is desirable that the second clock error be smaller than the first clock error. Therefore, a case where the tolerance of the clock frequency of the second clock signal is negligibly small as compared with the tolerance of the clock frequency of the first clock signal (for example, about 1/10 or less of the tolerance) will be described below as one example. This situation can be achieved by using, for example, a crystal oscillator as an oscillator included in the second clock 121C.

The voltage sensor calibration circuit 122 is a circuit controlled by the controller 111 when the voltage sensor 114 is calibrated.

The current sensor calibration circuit 123 is a circuit controlled by the controller 111 when the current sensor 115 is calibrated.

The display 124 displays information regarding calibration of the control circuit 11 under the control of the controller 111. The display 124 is, for example, an LED. In this case, the display 124 displays a blinking pattern of light indicating information regarding calibration of the control circuit 11. The display 124 may be, for example, a display instead of the LED.

The DC power circuit 125 generates a plurality of DC voltages having different magnitudes on the basis of the AC voltage supplied from the AC power supply 13. For example, the DC power circuit 125 generates a power-supply voltage of the calibration circuit 12. For convenience of description, the power-supply voltage is indicated by VDD in the following description. The DC power circuit 125 is, for example, an AC (Alternating Current)/DC converter.

The AC power supply 13 is a power supply that supplies an AC voltage. The AC power supply 13 is, for example, a commercial power supply. The AC power supply 13 may be another power supply that supplies an AC voltage instead of the commercial power supply. Further, the AC power supply 13 may be provided in the calibration system 1 or may not be provided in the calibration system 1.

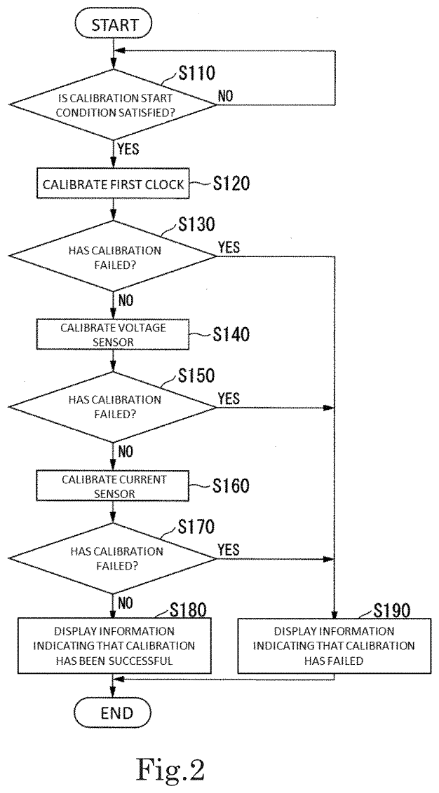

A process performed by the control circuit 11 for calibrating the control circuit 11 using the calibration circuit 12 will be described below. FIG. 2 is a diagram showing an example of a processing routine of the process performed by the control circuit 11 for calibrating the control circuit 11 using the calibration circuit 12. A case in which the control circuit 11 is connected to the calibration circuit 12 at a timing before the process in step S110 shown in FIG. 2 is performed will be described below as one example.

The controller 111 waits until the calibration start condition is satisfied (step S110).

When determining that the calibration start condition is satisfied (step S110—YES), the controller 111 performs calibration of the first clock 113 (step S120). Here, the process of step S120 will be described in detail.

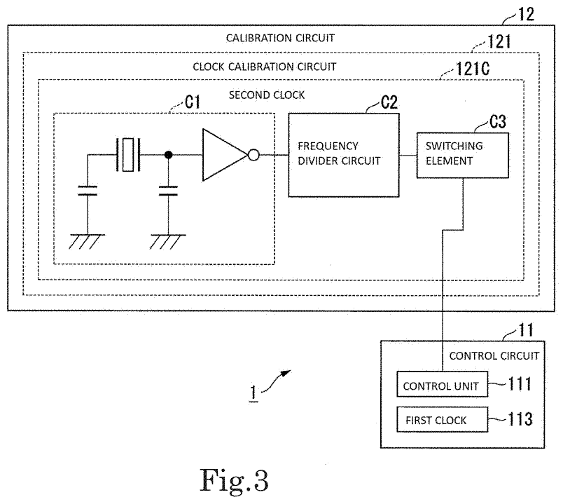

The controller 111 controls the clock calibration circuit 121 to acquire a second clock signal generated by the second clock 121C provided in the clock calibration circuit 121. The controller 111 calibrates the first clock 113 on the basis of the acquired second clock signal. The controller 111 performs the process described above as the process of step S120. However, the detail of the process of step S120 differs depending on the circuit configuration of the clock calibration circuit 121. In the following, the process of step S120 when the clock calibration circuit 121 has the circuit configuration shown in FIG. 3 will be described as one example. FIG. 3 is a diagram showing an example of the circuit configuration of the clock calibration circuit 121. In order to avoid the complexity of illustration, functional units other than the controller 111 and the first clock 113 among the functional units included in the control circuit 11 are not illustrated in FIG. 3. Further, in order to avoid the complexity of illustration, functional units other than the clock calibration circuit 121 among the functional units included in the calibration circuit 12 are not illustrated in FIG. 3.

In the example shown in FIG. 3, the second clock 121C included in the clock calibration circuit 121 includes an oscillation circuit C1, a frequency divider circuit C2, and a switching element C3. An output terminal of the oscillation circuit C1 is connected to an input terminal of the frequency divider circuit C2. An output terminal of the frequency divider circuit C2 is connected to a terminal that is conductive when the switching element C3 is on, out of two terminals of the switching element C3. In the connection state, the other of the two terminals is connected to the controller 111 as shown in FIG. 3. The two terminals are, for example, a source terminal and a drain terminal when the switching element C3 is a field-effect transistor.

The oscillation circuit C1 has, for example, a crystal oscillator, a capacitor, and an amplifier. The oscillation circuit C1 generates a clock signal having a predetermined clock frequency. The clock frequency is, for example, 32.768 kHz. The oscillation circuit C1 outputs the generated clock signal to the frequency divider circuit C2. Note that the oscillation circuit C1 may have another oscillator instead of the crystal oscillator. Further, the clock frequency may be lower than 32.768 kHz or higher than 32.768 kHz.

The frequency divider circuit C2 divides the frequency of the clock signal obtained from the oscillation circuit C1. The frequency divider circuit C2 divides the clock signal by, for example, eight. When the clock frequency of the clock signal is 32.768 kHz, the clock frequency of the clock signal after being divided by eight by the frequency divider circuit C2 is 128 Hz. The frequency divider circuit C2 outputs the clock signal after the frequency division to the switching element C3 as the abovementioned second clock signal. That is, the second clock frequency in this example is 128 Hz. Note that the frequency divider circuit C2 may divide the clock signal by a number smaller than eight or greater than eight, instead of dividing the clock signal by eight.

The frequency divider circuit C2 is composed of, for example, a counter circuit. The frequency divider circuit C2 may be composed of a flip-flop or another circuit instead of the counter circuit.

The switching element C3 is, for example, a field-effect transistor. Note that the switching element C3 may be another switching element such as a bipolar transistor instead of the field-effect transistor. The switching element C3 switches the state of the switching element C3 between an on state and an off state according to a control signal from the controller 111. When the switching element C3 is in an on state in the connection state, the switching element C3 outputs the second clock signal output from the output terminal of the frequency divider circuit C2 to the controller 111. When the switching element C3 is in an off state in the connection state, the switching element C3 does not output the second clock signal output from the output terminal of the frequency divider circuit C2 to the controller 111.

The controller 111 calibrates the first clock 113 on the basis of the second clock signal output from the clock calibration circuit 121 including the second clock 121C described above. More specifically, the controller 111 calculates, as a first actual measured value, a number-of-clock-pulse counted value of the first clock signal per cycle of the second clock signal acquired from the second clock 121C. Here, when calculating the first actual measured value, the controller 111 acquires the first clock signal from the first clock 113. The first actual measured value is calculated using, for example, an input capture function of a microcomputer including the controller 111. In addition, the controller 111 specifies, as a first nominal value, a number-of-clock-pulse counted value of the first clock signal per one cycle when the clock frequency of the first clock signal matches the first clock frequency. The controller 111 calculates a value obtained by dividing the calculated first actual measured value by the specified first nominal value as a first correction coefficient. That is, the controller 111 calculates the first correction coefficient on the basis of following Equation (1).

(First correction coefficient)=(First actual measured value)/(First nominal value) (1)

The controller 111 stores first correction coefficient information indicating the first correction coefficient calculated based on the Equation (1) in the storage unit 112. Thus, the controller 111 can correct the first clock frequency of the first clock signal using the first correction coefficient. The controller 111 completes the calibration of the first clock 113 when storing the first correction coefficient information in the storage unit 112.

Here, the controller 111 performs the correction of the first clock frequency using the first correction coefficient by multiplying a PWM (Pulse Width Modulation) timer counter nominal value by the first correction coefficient. For example, when performing PWM control of the motor M, the controller 111 calculates a PWM timer counter value by multiplying the PWM timer counter nominal value by the first correction coefficient. Then, the controller 111 performs PWM control of the motor M on the basis of the calculated PWM timer counter value. Thus, the controller 111 can calculate a value calculated based on the clock frequency of the first clock signal with higher accuracy, as compared to the case where the first clock 113 is not calibrated. The abovementioned value is, for example, a PWM cycle, a rotation speed of the motor M, or the like. That is, the control circuit 11 can reduce individual differences regarding first clocks 113. In this example, the calibration of the first clock 113 is automatically performed by connecting the control circuit 11 to the calibration circuit 12. That is, the control circuit 11 can calibrate the first clock 113 only by connecting the control circuit 11 to the calibration circuit 12 as a work step necessary for calibrating the first clock 113. As a result, the control circuit 11 can reduce individual differences regarding first clocks 113 while suppressing an increase in manufacturing cost. In other words, the control circuit 11 enables reduction in individual differences among control circuits 11 while suppressing an increase in manufacturing cost.

After the process of step S120 is performed, the controller 111 determines whether the calibration of the first clock 113 has failed by the process of step S120 (step S130). Here, the process of step S130 will be described.

When the first correction coefficient assumes a value included in, for example, a predetermined first range, the controller 111 determines that the calibration of the first clock 113 has been successful in step S120. On the other hand, when the first correction coefficient assumes a value not included within the first range, the controller 111 determines that the calibration of the first clock 113 has failed in step S120. The first range is determined according to, for example, the tolerance of the clock frequency of the first clock signal. When the tolerance is ±2%, the first range is a range of 1.00±0.02 (that is, a range having a margin of error of ±2%, which is the same as the tolerance, with respect to 1.00). Thus, the controller 111 can determine, for example, whether the first clock 113 is defective by the process of step S130. This is because, in this case, the first correction coefficient assuming a value not included in the first range means that the clock frequency of the first clock signal is unacceptably deviated from the first clock frequency. Note that the first range may be determined irrespective of the tolerance. In this case, the first range may be an arbitrary range.

When determining that the calibration of the first clock 113 has failed by the process of step S120 (step S130—YES), the controller 111 displays information indicating that the calibration has failed in the display 124 (step S190), and ends the processing routine. More specifically, in this case, the controller 111 displays a blinking pattern of light indicating the abovementioned information in the display 124 in the example embodiment.

On the other hand, when determining that the calibration of the first clock 113 has been successful by the process of step S120 (step S130—NO), the controller 111 performs calibration of the voltage sensor 114 (step S140). Here, the process of step S140 will be described in detail.

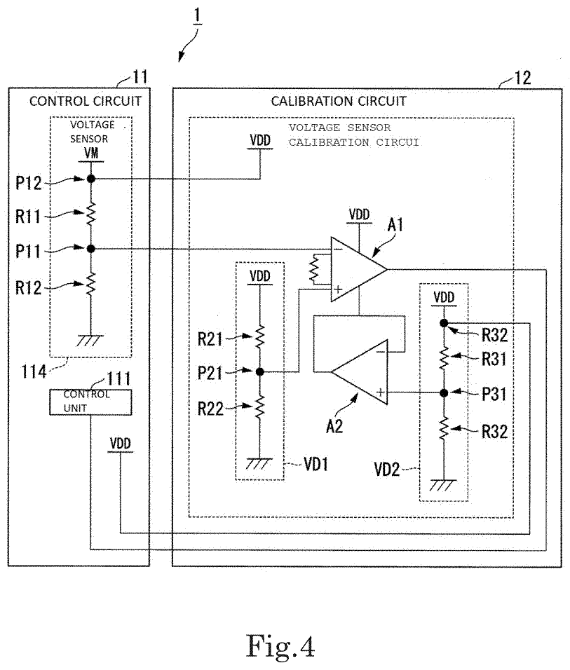

The controller 111 controls the voltage sensor calibration circuit 122 to calibrate the voltage sensor 114. More specifically, the controller 111 outputs the power-supply voltage VDD to the voltage sensor 114 by the voltage sensor calibration circuit 122, and causes the voltage sensor 114 to detect the power-supply voltage VDD. Further, the controller 111 causes the voltage sensor calibration circuit 122 to detect the power-supply voltage VDD. Then, the controller 111 calibrates the voltage sensor 114 on the basis of the difference between the detection result by the voltage sensor 114 and the detection result by the voltage sensor calibration circuit 122. The controller 111 performs the process described above as the process of step S140. However, the detail of the process of step S140 differs depending on the circuit configuration of the voltage sensor 114 and the circuit configuration of the voltage sensor calibration circuit 122. In the following, the process of step S140 when the voltage sensor 114 and the voltage sensor calibration circuit 122 have circuit configurations shown in FIG. 4, respectively, will be described as one example. FIG. 4 is a diagram showing the circuit configuration of the voltage sensor 114 and the circuit configuration of the voltage sensor calibration circuit 122. Note that, in order to avoid the complexity of illustration, functional units other than the controller 111 and the voltage sensor 114 among the functional units included in the control circuit 11 are not illustrated in FIG. 4. Further, in order to avoid the complexity of illustration, functional units other than the voltage sensor calibration circuit 122 among the functional units included in the calibration circuit 12 are not illustrated in FIG. 4.

In the example shown in FIG. 4, the voltage sensor 114 detects a power-supply voltage VM in the non-connection state. For this reason, the voltage sensor 114 has a voltage divider circuit including resistors R11 and R12 as shown in FIG. 4. Note that, in order to avoid the complexity of illustration, circuit configurations of components other than the voltage divider circuit in the circuit configuration of the voltage sensor 114 are not illustrated in FIG. 4. The voltage divider circuit is an example of a first voltage divider circuit.

For convenience of description, the resistance value of the resistor R11 is indicated by RH in the following description. Here, the resistance value of the resistor R11 may deviate from a nominal value of the resistance value RH within a range of tolerance of the resistance value RH of the resistor R11 due to a manufacturing error of the resistor R11. For convenience of description, a case will be described below in which the resistor R11 is manufactured with such an accuracy that the resistance value RH deviates within a range of NRH (1.00±ΔRH). Here, NRH indicates a nominal value of the resistance value RH. ΔRH is a ratio indicating a tolerance of the resistance value RH.

For convenience of description, the resistance value of the resistor R12 is indicated by RL in the following description. Here, the resistance value of the resistor R12 may deviate from a nominal value of the resistance value RL within a range of tolerance of the resistance value RL of the resistor R12 due to a manufacturing error of the resistor R12. For convenience of description, a case will be described below in which the resistor R12 is manufactured with such an accuracy that the resistance value RL deviates within a range of NRL (1.00±ΔRL). Here, NRL indicates a nominal value of the resistance value RL. ΔRL is a ratio indicating a tolerance of the resistance value RL.

In the voltage divider circuit of the voltage sensor 114, the power-supply voltage VM is supplied to one of terminals of the resistor R11 in the non-connection state. Here, the supply of the power-supply voltage VM to the resistor R11 is controlled by the controller 111. In the voltage divider circuit, the other of the terminals of the resistor R11 is connected to one of terminals of the resistor R12. In the voltage divider circuit, the other terminal of the resistor R12 is grounded. In the voltage sensor 114 having the voltage divider circuit described above, a voltage after the power-supply voltage VM is divided by the resistors R11 and R12 appears at a connection point P11 between the resistors R11 and R12. The voltage sensor 114 detects the power-supply voltage VM on the basis of the voltage appearing at the connection point P11. Therefore, the error of the power-supply voltage VM detected by the voltage sensor 114 is caused by manufacturing errors of the resistance values RH and RL as described above.

On the other hand, in the voltage divider circuit of the voltage sensor 114, the power-supply voltage VDD is supplied to the resistor R11 via a connection point P12 between the power-supply voltage VM and the resistor R11 in the connection state. Here, the supply of the power-supply voltage VDD to the resistor R11 is controlled by the controller 111. In the connection state, the power-supply voltage VM is not supplied to the resistor R11. As a result, a voltage after the power-supply voltage VDD is divided by the resistors R11 and R12 appears at the connection point P11. For convenience of description, the abovementioned voltage is referred to as a first detection voltage and is indicated by V− in the following description. The first detection voltage V− is calculated based on following Equations (2) and (3) using the resistance value RL and the resistance value RH.

(V−)=(First voltage division ratio)×VDD (2)

(First voltage division ratio)=(RL/(RL+RH)) (3)

The first voltage division ratio in Equation (2) is defined by Equation (3). The first detection voltage V− calculated by Equation (2) is an example of a detection result by the voltage sensor 114 described above. Here, in the connection state, the connection point P11 is connected to the voltage sensor calibration circuit 122. Therefore, the first detection voltage V− is output to the voltage sensor calibration circuit 122 in the connection state.

On the other hand, in the example shown in FIG. 4, the voltage sensor calibration circuit 122 includes an instrumentation amplifier A1, a voltage divider circuit VD1, a voltage divider circuit VD2, and a voltage follower A2. Note that the voltage divider circuit VD1 is an example of a second voltage divider circuit. The combination of the voltage divider circuit VD2 and the voltage follower A2 is an example of an output voltage generation circuit.

The instrumentation amplifier A1 is driven by the power-supply voltage VDD. The instrumentation amplifier A1 amplifies the difference between the voltage input to an inverting input terminal of the instrumentation amplifier A1 and the voltage input to a non-inverting input terminal of the instrumentation amplifier A1. The abovementioned first detection voltage V− is supplied to the inverting input terminal of the instrumentation amplifier A1 while the control circuit 11 is connected to the calibration circuit 12. This is because the connection point P11 is connected to the inverting input terminal in the connection state. A second detection voltage is supplied to the non-inverting input terminal of the instrumentation amplifier A1 from the voltage divider circuit VD1 described later. That is, the instrumentation amplifier A1 amplifies the difference between the first detection voltage and the second detection voltage. Note that the amplification factor of the difference by the instrumentation amplifier A1 is determined in advance. For convenience of description, the amplification factor is indicated by A in the following description. The instrumentation amplifier A1 outputs, as an output voltage of the instrumentation amplifier A1, a value obtained by adding a reference voltage output from the voltage follower A2 described later to the difference amplified by A-fold. Therefore, an output terminal of the voltage follower A2 is connected to the reference input terminal of the instrumentation amplifier A1.

The output terminal of the instrumentation amplifier A1 is connected to one of a plurality of A (Analog)/D (Digital) converters included in the controller 111 in the connection state. In the connection state, the controller 111 is supplied with the power-supply voltage VDD. The controller 111 uses the power-supply voltage VDD supplied to the controller 111 as a reference voltage of the A/D converter connected to the output terminal, from among the plurality of A/D converters, in the connection state.

The voltage divider circuit VD1 is used for detecting the power-supply voltage VDD in the voltage sensor calibration circuit 122. The voltage divider circuit VD1 includes resistors R21 and R22. The power-supply voltage VDD is an example of a reference voltage.

For convenience of description, the resistance value of the resistor R21 is indicated by RH* in the following description. Here, the resistance value of the resistor R21 may deviate from a nominal value of the resistance value within a range of tolerance of the resistance value of the resistor R21 due to a manufacturing error of the resistor R21. For convenience of description, a case will be described below in which the resistor R21 is manufactured with such an accuracy that the resistance value RH* deviates within a range of NRH* (1.00±ΔRH*). Here, NRH* indicates a nominal value of the resistance value RH*. ΔRH* is a ratio indicating the tolerance of the resistance value RH*. Here, the resistor R21 has the resistance value NRH* equal to the resistance value NRH. The resistor R21 has ΔRH* which is smaller than ΔRH. When ΔRH* is negligibly small (for example, approximately 1/10 or less of ΔRH) as compared with ΔRH, ΔRH* can be treated as approximately 0. Therefore, a case where ΔRH* is negligibly small compared to ΔRH will be described below as an example.

For convenience of description, the resistance value of the resistor R22 is indicated by RL* in the following description. Here, the resistance value of the resistor R22 may deviate from a nominal value of the resistance value within a range of tolerance of the resistance value of the resistor R22 due to a manufacturing error of the resistor R22. For convenience of description, a case will be described below where the resistor R22 is manufactured with such an accuracy that the resistance value RL* deviates within a range of NRL* (1.00±ΔRL*). Here, NRL* indicates a nominal value of the resistance value RL*. ΔRL* is a ratio indicating a tolerance of the resistance value RL*. Here, the resistor R22 has the resistance value NRL* equal to the resistance value NRL. The resistor R22 has ΔRL* which is smaller than ΔRL. When ΔRL* is negligibly small (for example, approximately 1/10 or less of ΔRL) as compared with ΔRL, ΔRL* can be treated as approximately 0. Therefore, a case where ΔRL* is negligibly small compared to ΔRL will be described below as an example.

In the voltage divider circuit VD1, the power-supply voltage VDD is supplied to one of terminals of the resistor R21. Here, the supply of the power-supply voltage VDD to the resistor R21 is controlled by the controller 111. In the voltage divider circuit VD1, the other of the terminals of the resistor R21 is connected to one of terminals of the resistor R22. In the voltage divider circuit VD1, the other terminal of the resistor R22 is grounded.

As described above, the voltage divider circuit VD1 has the same structure as the structure of the voltage divider circuit included in the voltage sensor 114, and has the resistors (that is, the resistor R21 and the resistor R22) having tolerances smaller than the tolerances of the resistors (that is, the resistor R11 and the resistor R12) of the voltage divider circuit in the voltage sensor 114.

In the voltage divider circuit VD1 configured as described above, a voltage after the power-supply voltage VDD is divided by the resistors R21 and R22 appears at a connection point P21 between the resistors R21 and R22. This voltage is the second detection voltage described previously. For convenience of description, the second detection voltage is indicated by V+ in the following description. The second detection voltage V+ is calculated based on following Equations (4) and (5) using the resistance values RL* and RH*.

(V+)=(Second voltage division ratio)×VDD (4)

(Second voltage division ratio)=(RL*/(RL*+RH*)) (5)

The second voltage division ratio in Equation (4) is defined by Equation (5). The second detection voltage V+ calculated according to Equation (4) is an example of a detection result by the voltage sensor calibration circuit 122 described above. Here, the connection point P21 is connected to the non-inverting input terminal of the instrumentation amplifier A1. Therefore, as described above, the second detection voltage V+ is supplied to the non-inverting input terminal.

Here, the instrumentation amplifier A1 amplifies the difference between the first detection voltage and the second detection voltage by A-fold, and outputs, as an output voltage, a value obtained by adding the reference voltage output from the voltage follower A2 to the amplified difference. When the reference voltage is indicated by VR and the output voltage is indicated by Vdf, the output voltage output from the instrumentation amplifier A1 is represented by following Equation (6).

Vdf=A×((V+)−(V−))+VR (6)

The reference voltage VR in Equation (6) is supplied by the voltage divider circuit VD2 and the voltage follower A2.

The voltage divider circuit VD2 generates the reference voltage VR by dividing the power-supply voltage VDD. The voltage divider circuit VD2 includes resistors R31 and R32.

There is no particular limitation on the tolerances of the resistance values of the resistors R31 and R32. However, the tolerances are desirably small. Therefore, a case where the tolerances of the resistance values of the resistors R31 and R32 are substantially equal to the tolerances of the resistance values of the resistors R21 and R22 will be described below as one example.

Here, the resistance value of the resistor R31 and the resistance value of the resistor R32 are determined according to the voltage value of the reference voltage VR. The reference voltage VR may have any voltage value as long as it is lower than the voltage value of the power-supply voltage VDD. However, the voltage value of the reference voltage VR is preferably (VDD/2) from the viewpoint of voltage detection. Therefore, a case where the reference voltage VR is (VDD/2) will be described below. In this case, the resistors R31 and R32 have the same resistance value.

In the voltage divider circuit VD2, the power-supply voltage VDD is supplied to one of terminals of the resistor R31. Here, the supply of the power-supply voltage VDD to the resistor R31 is controlled by the controller 111. In the voltage divider circuit VD2, the other of the terminals of the resistor R31 is connected to one of terminals of the resistor R32. In the voltage divider circuit VD2, the other terminal of the resistor R32 is grounded. In the voltage divider circuit VD2 configured as described above, a voltage after the power-supply voltage VDD is divided by the resistors R31 and R32, that is, the reference voltage VR, appears at a connection point P31 between the resistors R31 and R32.

The connection point P31 of the voltage divider circuit VD2 configured as described above is connected to the non-inverting input terminal of the voltage follower A2. Therefore, the reference voltage VR is output from the output terminal of the voltage follower A2. The output terminal is connected to the reference input terminal of the instrumentation amplifier A1. The reason why the voltage follower A2 is provided between the reference input terminal and the connection point P31 is to prevent a voltage drop at the connection point P31 due to an input impedance of the voltage follower A2.

Here, in the connection state, the controller 111 is supplied with the output voltage Vdf from the output terminal of the instrumentation amplifier A1 as described above. The controller 111 calculates a second correction coefficient on the basis of the supplied output voltage Vdf. The second correction coefficient can be calculated by following Equations (7) and (8), where the second correction coefficient is indicated by HC2.

HC2=(1.00/MX)×(Vdf−(VDD/2))+1.00 (7)

MX=A×VDD×(Second voltage division ratio) (8)

Equations (7) and (8) can be made based on the variation in the first voltage division ratio with respect to the second voltage division ratio. This is because the variation in the output voltage Vdf is caused by the variation in the first voltage division ratio with respect to the second voltage division ratio, as can be seen from Equations (2) to (6) mentioned above. The variation in the first voltage division ratio with respect to the second voltage division ratio is represented by a voltage-division-ratio variation ratio shown in following Equations (9) to (11).

(Voltage-division-ratio variation ratio)(First voltage division ratio)/(Second voltage division ratio) (9)

(Maximum value of voltage-division-ratio variation ratio)=(Maximum value of first voltage division ratio)/(Second voltage division ratio) (10)

(Minimum value of voltage-division-ratio variation ratio)=(Minimum value of first voltage division ratio)/(Second voltage division ratio) (11)

Here, when the first voltage division ratio is greater than the second voltage division ratio, the first detection voltage V− becomes greater than the second detection voltage V+. Therefore, in this case, the output voltage Vdf output from the instrumentation amplifier A1 is smaller than VDD/2. Under such circumstances, the second correction coefficient HC2 is expected to assume a value smaller than 1.00. On the other hand, when the first voltage division ratio is smaller than the second voltage division ratio, the first detection voltage V− becomes smaller than the second detection voltage V+. Therefore, in this case, the output voltage Vdf output from the instrumentation amplifier A1 is greater than VDD/2. Under such circumstances, the second correction coefficient HC2 is expected to assume a value greater than 1.00. From the above, it is appropriate that the second correction coefficient HC2 is represented by Equations (7) and (8) mentioned above.

For example, when ΔRL=ΔRH=0.01 and RL<<RH, it is considered that the first detection voltage V− deviates from the second detection voltage V+ by about 2%. If the resistance value NRH is 660 kΩ and the resistance value NRL is 10 kΩ, the second detection voltage V+ is approximately (0.0149×VDD). In this case, if the amplification factor is 1000, Equations (7) and (8) are rewritten into following Equation (9).

HC2=(0.02/(1.49×VDD))×(Vdf−(VDD/2))+1.00 (9)

As described above, in the connection state, the controller 111 calculates the second correction coefficient HC2 on the basis of Equations (7) and (8), the supplied output voltage Vdf, and the supplied power-supply voltage VDD. The controller 111 stores second correction coefficient information indicating the calculated second correction coefficient HC2 into the storage unit 112. Thus, the controller 111 can correct the power-supply voltage VM detected by the voltage sensor 114 using the second correction coefficient HC2. That is, the controller 111 completes the calibration of the voltage sensor 114 when storing the second correction coefficient information in the storage unit 112.

Here, the controller 111 corrects the power-supply voltage VM detected by the voltage sensor 114 using the second correction coefficient HC2 by multiplying the power-supply voltage VM by the second correction coefficient HC2. Thus, the controller 111 can calculate a value calculated based on the power-supply voltage VM with higher accuracy, as compared to the case where the voltage sensor 114 is not calibrated. That is, the control circuit 11 can reduce individual differences regarding voltage sensors 114. In this example, the calibration of the voltage sensor 114 is automatically performed by connecting the control circuit 11 to the calibration circuit 12. That is, the control circuit 11 can calibrate the voltage sensor 114 only by connecting the control circuit 11 to the calibration circuit 12 as a work step necessary for calibrating the voltage sensor 114. As a result, the control circuit 11 can reduce individual differences regarding voltage sensors 114 while suppressing an increase in manufacturing cost. In other words, the control circuit 11 enables reduction in individual differences among control circuits 11 while suppressing an increase in manufacturing cost.

After the process of step S140 is performed, the controller 111 determines whether the calibration of the voltage sensor 114 has failed by the process of step S140 (step S150). Here, the process of step S150 will be described.

When the second correction coefficient HC2 assumes a value included in, for example, a predetermined second range, the controller 111 determines that the calibration of the voltage sensor 114 has been successful in step S140. On the other hand, when the second correction coefficient HC2 assumes a value not included within the second range, the controller 111 determines that the calibration of the voltage sensor 114 has failed in step S140. The second range is, for example, a range from the maximum value of the voltage-division-ratio variation ratio calculated according to Equation (10) to the minimum value of the voltage-division-ratio variation ratio calculated according to Equation (11). Thus, the controller 111 can determine, for example, whether the voltage sensor 114 is defective by the process of step S140. This is because, when the second range is determined as the range described above, the second correction coefficient HC2 assuming a value not included in the second range means that the resistance values of the resistors R11 and R12 unacceptably deviate from their nominal values. Note that the second range may be determined by another method instead of being determined as the range described above. Further, the second range may be narrower than the range from the maximum value of the voltage-division-ratio variation ratio to the minimum value of the voltage-division-ratio variation ratio, or may be wider than the range from the maximum value of the voltage-division-ratio variation ratio to the minimum value of the voltage-division-ratio variation ratio.

When determining that the calibration of the voltage sensor 114 has failed by the process of step S140 (step S150—YES), the controller 111 proceeds to step S190 to display information indicating that the calibration has failed in the display 124, and ends this processing routine. More specifically, in this case, the controller 111 displays a blinking pattern of light indicating the abovementioned information in the display 124 in the example embodiment.

On the other hand, when determining that the calibration of the voltage sensor 114 has been successful by the process of step S140 (step S150—NO), the controller 111 performs calibration of the current sensor 115 (step S160). Here, the process of step S160 will be described in detail.

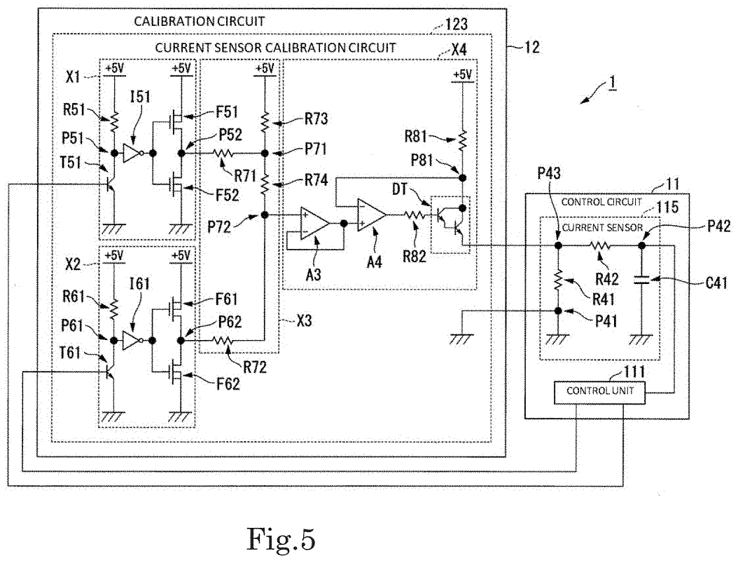

The controller 111 controls the current sensor calibration circuit 123 to calibrate the current sensor 115. More specifically, the controller 111 controls the current sensor calibration circuit 123 to output a plurality of currents having different magnitudes from the current sensor calibration circuit 123 to the current sensor 115. Then, the controller 111 calibrates the current sensor 115 on the basis of the detection results of the plurality of currents by the current sensor 115. The controller 111 performs the process described above as the process of step S160. However, the detail of the process of step S160 differs depending on the circuit configuration of the current sensor 115 and the circuit configuration of the current sensor calibration circuit 123. In the following, the process of step S160 when the current sensor 115 and the current sensor calibration circuit 123 have circuit configurations shown in FIG. 5, respectively, will be described as one example. FIG. 5 is a diagram showing the circuit configuration of the current sensor 115 and the circuit configuration of the current sensor calibration circuit 123. In order to avoid the complexity of illustration, functional units other than the controller 111 and the current sensor 115 among the functional units included in the control circuit 11 are not illustrated in FIG. 5. Further, in order to avoid the complexity of illustration, functional units other than the current sensor calibration circuit 123 among the functional units included in the calibration circuit 12 are not illustrated in FIG. 5.

The current sensor 115 converts the supplied current into a voltage. The controller 111 can calculate the current value of the current supplied to the current sensor 115 on the basis of the voltage converted by the current sensor 115 as described above.

The current sensor 115 has a resistor R41 which is a shunt resistor, a resistor R42 functioning as a filter for removing high-frequency noise, and a capacitor C41. One of terminals of the resistor R41 is connected to one of terminals of the resistor R42. The other of the terminals of the resistor R41 is connected to the ground of the control circuit 11. A connection point P41 between the resistor R41 and the ground is connected to the ground of the calibration circuit 12 in the connection state. As a result, the control circuit 11 and the calibration circuit 12 have a common (or substantially common) ground potential. The other of the terminals of the resistor R42 is connected to one of terminals of the capacitor C41. The other of the terminals of the capacitor C41 is connected to the ground of the control circuit 11. A connection point P42 between the resistor R42 and the capacitor C41 is connected to one of the plurality of A/D converters included in the controller 111. A connection point P43 between the resistors R41 and R42 is connected to an output terminal from which current is output from the current sensor calibration circuit 123 in the connection state.

Due to the circuit configuration described above, the current sensor 115 converts the current supplied to the connection point P43 into a voltage. Note that, in order to avoid the complexity of illustration, the circuit configuration for supplying a current to the connection point P43 in the control circuit 11 is not illustrated in FIG. 5.

In the connection state, the current sensor calibration circuit 123 sequentially outputs multiple currents having different current values to the current sensor 115 in accordance with the control by the controller 111. In the following, a case where four currents are used as the multiple currents will be described as an example. In the following, a case where the four currents have a combination of current values of 0 A, 0.1 A, 0.2 A, and 0.3 A will be described as one example. Note that the four currents may have another combination of current values instead of the above combination.

The current sensor calibration circuit 123 includes a first circuit X1, a second circuit X2, a third circuit X3, and a fourth circuit X4.

The first circuit X1 outputs two voltages having different voltage values in accordance with the control by the controller 111. In the example illustrated in FIG. 5, the first circuit X1 outputs either 0 V or 5 V in accordance with the control. Note that the combination of voltage values of the two voltages output by the first circuit X1 in accordance with the control may be another combination of voltage values.

The first circuit X1 includes a transistor T51, an inverter 151, a resistor R51, a field-effect transistor F51, and a field-effect transistor F52.

The transistor T51 functions as a switch that switches between outputting 0 V from the first circuit X1 and outputting 5 V from the first circuit X1. The transistor T51 is, for example, an NPN transistor. The first circuit X1 outputs 5 V when 0 V is supplied to a base terminal of the transistor T51. On the other hand, the first circuit X1 outputs 0 V when 5 V is supplied to the base terminal of the transistor T51. For convenience of description, the voltage of 0 V output from the controller 111 will be referred to as an L-level voltage below. For convenience of description, the voltage of 5 V output from the controller 111 will be referred to as an H-level voltage below. Note that the transistor T51 may be another switching element such as a relay switch.

The base terminal of the transistor T51 is connected to an input terminal of the first circuit X1. The input terminal is connected to one of a plurality of output terminals of the controller 111 in the connection state. Thus, the controller 111 can control conduction between an emitter terminal of the transistor T51 and a collector terminal of the transistor T51.

The emitter terminal of the transistor T51 is connected to the ground of the calibration circuit 12. The collector terminal of the transistor T51 is connected to one of terminals of the resistor R51. The other of the terminals of the resistor R51 is supplied with a voltage VX generated by the DC power circuit 125. The voltage VX is, for example, 5 V. Note that “+5 V” shown in FIG. 5 indicates the voltage VX. The voltage VX may have a voltage value lower than 5 V or a voltage value higher than 5 V, instead of 5 V.

A connection point P51 between the transistor T51 and the resistor R51 is connected to an input terminal of the inverter 151.

The inverter 151 is a NOT gate. The field-effect transistor F51 and the field-effect transistor F52 are connected in parallel between the output terminal of the inverter 151 and an output terminal of the first circuit X1.

The field-effect transistor F51 is a P-type field-effect transistor. The field-effect transistor F52 is an N-type field-effect transistor. Note that the field-effect transistor F51 may be an N-type field-effect transistor. In this case, the field-effect transistor F52 is a P-type field-effect transistor.

A gate terminal of the field-effect transistor F51 and a gate terminal of the field-effect transistor F52 are connected to the output terminal of the inverter 151. The voltage VX is supplied to a source terminal of the field-effect transistor F51. A drain terminal of the field-effect transistor F51 is connected to a drain terminal of the field-effect transistor F52. A source terminal of the field-effect transistor F52 is connected to the ground of the calibration circuit 12. A connection point P52 between the drain terminal of the field-effect transistor F51 and the drain terminal of the field-effect transistor F52 is connected to the output terminal of the first circuit X1.

Here, for convenience of description, a state in which the L-level voltage is supplied to the base terminal of the transistor T51 from the controller 111 will be referred to as an off state of the transistor T51 below. For convenience of description, a state in which the H-level voltage is supplied to the base terminal of the transistor T51 from the controller 111 will be referred to as an on state of the transistor T51 below. For convenience of description, a state in which a voltage of 0 V is supplied to the gate terminal of the field-effect transistor F51 will be referred to as an on state of the field-effect transistor F51 below. For convenience of description, a state in which a voltage of 5 V is supplied to the gate terminal of the field-effect transistor F51 will be referred to as an off state of the field-effect transistor F51 below. For convenience of description, a state in which a voltage of 0 V is supplied to the gate terminal of the field-effect transistor F52 will be referred to as an off state of the field-effect transistor F52 below. For convenience of description, a state in which a voltage of 5 V is supplied to the gate terminal of the field-effect transistor F52 will be referred to as an on state of the field-effect transistor F52 below.

When the transistor T51 is in an off state, the field-effect transistor F51 is in an on state. In this case, the field-effect transistor F52 is in an off state. Therefore, in this case, a voltage of 5 V is output from the output terminal of the first circuit X1.

On the other hand, when the transistor T51 is in an on state, the field-effect transistor F51 is in an off state. In this case, the field-effect transistor F52 is in an on state. Therefore, in this case, a voltage of 0 V is output from the output terminal of the first circuit X1.

The second circuit X2 outputs two voltages having different voltage values in accordance with the control by the controller 111. In the example illustrated in FIG. 5, the second circuit X2 outputs either 0 V or 5 V in accordance with the control. Note that the combination of voltage values of the two voltages output by the second circuit X2 in accordance with the control may be another combination of voltage values.

The second circuit X2 includes a transistor T61, an inverter 161, a resistor R61, a field-effect transistor F61, and a field-effect transistor F62.

The transistor T61 functions as a switch that switches between outputting 0 V from the second circuit X2 and outputting 5 V from the second circuit X2. The transistor T61 is, for example, an NPN transistor. The second circuit X2 outputs 5 V when 0 V is supplied to a base terminal of the transistor T61. On the other hand, the second circuit X2 outputs 0 V when 5 V is supplied to the base terminal of the transistor T61. Note that the transistor T61 may be another switching element such as a relay switch.

The base terminal of the transistor T61 is connected to an input terminal of the second circuit X2. The input terminal is connected to one of a plurality of output terminals of the controller 111 in the connection state. Thus, the controller 111 can control conduction between an emitter terminal of the transistor T61 and a collector terminal of the transistor T61.

The emitter terminal of the transistor T61 is connected to the ground of the calibration circuit 12. The collector terminal of the transistor T61 is connected to one of terminals of the resistor R61. The other of the terminals of the resistor R61 is supplied with the voltage VX generated by the DC power circuit 125.

A connection point P61 between the transistor T61 and the resistor R61 is connected to an input terminal of the inverter 161.

The inverter 161 is a NOT gate. The field-effect transistor F61 and the field-effect transistor F62 are connected in parallel between an output terminal of the inverter 161 and an output terminal of the second circuit X2.

The field-effect transistor F61 is a P-type field-effect transistor. The field-effect transistor F62 is an N-type field-effect transistor. Note that the field-effect transistor F61 may be an N-type field-effect transistor. In this case, the field-effect transistor F62 is a P-type field-effect transistor.

A gate terminal of the field-effect transistor F61 and a gate terminal of the field-effect transistor F62 are connected to the output terminal of the inverter 161. The voltage VX is supplied to a source terminal of the field-effect transistor F61. A drain terminal of the field-effect transistor F61 is connected to a drain terminal of the field-effect transistor F62. A source terminal of the field-effect transistor F62 is connected to the ground of the calibration circuit 12. A connection point P62 between the drain terminal of the field-effect transistor F61 and the drain terminal of the field-effect transistor F62 is connected to the output terminal of the second circuit X2.

Here, for convenience of description, a state in which the L-level voltage is supplied to the base terminal of the transistor T61 from the controller 111 will be referred to as an off state of the transistor T61 below. For convenience of description, a state in which the H-level voltage is supplied to the base terminal of the transistor T61 from the controller 111 will be referred to as an on state of the transistor T61 below. For convenience of description, a state in which a voltage of 0 V is supplied to the gate terminal of the field-effect transistor F61 will be referred to as an on state of the field-effect transistor F61 below. For convenience of description, a state in which a voltage of 5 V is supplied to the gate terminal of the field-effect transistor F61 will be referred to as an off state of the field-effect transistor F61 below. For convenience of description, a state in which a voltage of 0 V is supplied to the gate terminal of the field-effect transistor F62 will be referred to as an off state of the field-effect transistor F62 below. For convenience of description, a state in which a voltage of 5 V is supplied to the gate terminal of the field-effect transistor F62 will be referred to as an on state of the field-effect transistor F62 below.

When the transistor T61 is in an off state, the field-effect transistor F61 is in an on state. In this case, the field-effect transistor F62 is in an off state. Therefore, in this case, a voltage of 5 V is output from the output terminal of the second circuit X2.

On the other hand, when the transistor T61 is in an on state, the field-effect transistor F61 is in an off state. In this case, the field-effect transistor F62 is in an on state. Therefore, in this case, a voltage of 0 V is output from the output terminal of the second circuit X2.

The third circuit X3 outputs a voltage according to the voltage output from the first circuit X1 and the voltage output from the second circuit X2 by voltage division.

The third circuit X3 includes a resistor R71, a resistor R72, a resistor R73, and a resistor R74.

One of terminals of the resistor R71 is connected to the output terminal of the first circuit X1. The other of the terminals of the resistor R71 is connected to one of terminals of the resistor R73. The other of the terminals of the resistor R73 is supplied with the voltage VX. A connection point P71 between the resistors R71 and R73 is connected to one of terminals of the resistor R74. The other of the terminals of the resistor R74 is connected to one of the terminals of the resistor R72. The other of the terminals of the resistor R72 is connected to the output terminal of the second circuit X2. A connection point P72 between the resistors R74 and R72 is connected to an output terminal of the third circuit X3.

The third circuit X3 outputs a voltage according to the voltage output from the first circuit X1 and the voltage output from the second circuit X2 by the four resistors (i.e., the resistors R71 to R74) connected as described above.

For example, when the voltage value of the voltage output from the first circuit X1 is 5 V, and the voltage value of the voltage output from the second circuit X2 is 5 V, the third circuit X3 outputs a voltage of 5 V. In other words, when the transistor T51 is in an off state and the transistor T61 is in an off state, the third circuit X3 outputs a voltage of 5.00 V.

Further, for example, when the voltage value of the voltage output from the first circuit X1 is 0 V, and the voltage value of the voltage output from the second circuit X2 is 5 V, the third circuit X3 outputs a voltage of 3.75 V. In other words, when the transistor T51 is in an on state and the transistor T61 is in an off state, the third circuit X3 outputs a voltage of 3.75 V.

Further, for example, when the voltage value of the voltage output from the first circuit X1 is 5 V, and the voltage value of the voltage output from the second circuit X2 is 0 V, the third circuit X3 outputs a voltage of 2.50 V. In other words, when the transistor T51 is in an off state and the transistor T61 is in an on state, the third circuit X3 outputs a voltage of 2.50 V.

Further, for example, when the voltage value of the voltage output from the first circuit X1 is 0 V, and the voltage value of the voltage output from the second circuit X2 is 0 V, the third circuit X3 outputs a voltage of 1.25 V. In other words, when the transistor T51 is in an on state and the transistor T61 is in an on state, the third circuit X3 outputs a voltage of 1.25 V.

The fourth circuit X4 outputs four currents having different current values according to the voltage output from the third circuit X3.

The fourth circuit X4 includes a voltage follower A3, an operational amplifier A4, a resistor R81, a resistor R82, and a Darlington transistor DT.

A non-inverting input terminal of the voltage follower A3 is connected to an input terminal of the fourth circuit X4. The input terminal is connected to the output terminal of the third circuit X3. An output terminal of the voltage follower A3 is connected to a non-inverting input terminal of the operational amplifier A4. An inverting input terminal of the operational amplifier A4 is connected to one of terminals of the resistor R81. The other of the terminals of the resistor R81 is supplied with the voltage VX. A connection point P81 between the inverting input terminal and the resistor R81 is connected to a collector terminal of the Darlington transistor DT. A base terminal of the Darlington transistor DT is connected to one of terminals of the resistor R82. The other of the terminals of the resistor R82 is connected to an output terminal of the operational amplifier A4. An emitter terminal of the Darlington transistor DT is connected to an output terminal of the fourth circuit X4. The output terminal is connected to the output terminal of the current sensor calibration circuit 123. The output terminal is also connected to the connection point P43 of the current sensor 115 in the connection state.

Due to the circuit configuration described above, the fourth circuit X4 inputs a current according to the voltage output from the third circuit X3 to the base terminal of the Darlington transistor DT. Thus, the fourth circuit X4 can output four currents having different current values according to the voltage. The current value of each of the four currents can be adjusted by the resistance value of the resistor R81. In the following, a case where the four currents have a combination of current values of 0.0 A, 0.1 A, 0.2 A, and 0.3 A will be described as one example. Note that the four currents may have another combination of current values.

The current sensor 115 and the current sensor calibration circuit 123 have the circuit configurations as described above. Therefore, the controller 111 can output four currents having different magnitudes from the current sensor calibration circuit 123 to the current sensor 115 by controlling the current sensor calibration circuit 123.

Here, the controller 111 can specify the current value of the current output from the fourth circuit X4 to the current sensor 115 on the basis of the voltages output to the first circuit X1 and the second circuit X2. Therefore, the controller 111 specifies the current value of the current output from the fourth circuit X4 to the current sensor 115 as a first current value on the basis of the voltages output to each of the first circuit X1 and the second circuit X2. Further, when the current is output to the current sensor 115, the controller 111 specifies the current value of the current detected by the current sensor 115 as a second current value. Then, the controller 111 causes the storage unit 112 to store the combination of the first current value and the second current value. That is, the first current value and the second current value included in the combination are current values associated with each other. The controller 111 stores such a combination of the first current value and the second current value each time a voltage is output to each of the first circuit X1 and the second circuit X2. That is, in this example, the controller 111 repeats storing such a combination of the first current value and the second current value four times.

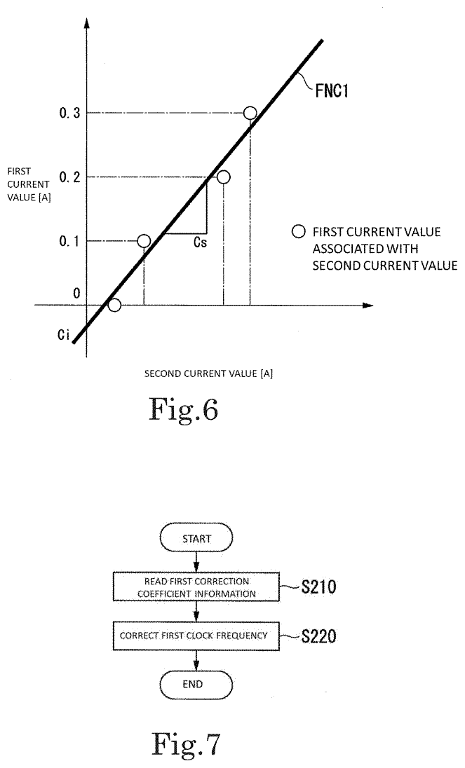

Here, the process of correcting a certain second current value is a process of matching or substantially matching the current value after the correction of the second current value with the first current value associated with the second current value. To this end, the controller 111 calculates a correction formula for correcting the current value of the current detected by the current sensor 115 by the least square method based on the stored four combinations. Specifically, the controller 111 calculates each of the slope and intercept of the linear function as shown in FIG. 6 by the least square method based on the stored four combinations. FIG. 6 is a diagram showing an example of a graph obtained by plotting the correspondence between the first current value and the second current value.

The vertical axis of the graph shown in FIG. 6 indicates the first current value. The horizontal axis of the graph indicates the second current value. The four points plotted on the graph show examples of points indicating the first current value associated with the second current value included in the four combinations stored in the storage unit 112 by the controller 111. The controller 111 calculates the slope and intercept of the straight line FNC1 shown in the graph by, for example, the least square method based on these four points. The straight line FNC1 shows an example of a regression line based on these four points and the least square method. The controller 111 causes the storage unit 112 to store information indicating the slope and intercept of the straight line FNC1 as correction formula information indicating a correction formula. In this example, when a current value of some current is detected by the current sensor 115, the controller 111 multiplies the detected current value by the slope, and calculates a value obtained by adding the intercept to the multiplied value. The obtained value is a current value obtained by correcting the current value. In other words, the controller 111 can correct the current value of the current detected by the current sensor 115 by storing the correction formula information in the storage unit 112. That is, the controller 111 completes the calibration of the current sensor 115 when storing the correction formula information in the storage unit 112. Note that the method of calculating the regression line by the least square method is known, and thus, the description thereof is omitted. Further, the controller 111 may use another method for calculating a regression line, in place of the least square method, in order to calculate the regression line based on the four points.

As described above, the controller 111 performs calibration of the current sensor 115. Accordingly, the controller 111 can reduce the difference between the current value of the current detected by the current sensor 115 and the actual current value of the current supplied to the current sensor 115, compared to the case where the calibration of the current sensor 115 is not performed. In other words, the controller 111 can reduce an error of the current value of the current detected by the current sensor 115, as compared to the abovementioned case. That is, the control circuit 11 can reduce individual differences regarding current sensors 115. In this example, the calibration of the current sensor 115 is automatically performed by connecting the control circuit 11 to the calibration circuit 12. That is, the control circuit 11 can calibrate the current sensor 115 only by connecting the control circuit 11 to the calibration circuit 12 as a work step necessary for calibrating the current sensor 115. As a result, the control circuit 11 can reduce individual differences regarding current sensors 115 while suppressing an increase in manufacturing cost. In other words, the control circuit 11 enables reduction in individual differences among control circuits 11 while suppressing an increase in manufacturing cost.

After the process of step S160 is performed, the controller 111 determines whether the calibration of the current sensor 115 has failed by the process of step S160 (step S170). Here, the process of step S170 will be described.

The controller 111 specifies a combination having the largest difference between the first current value and the second current value from among, for example, the four combinations stored in the storage unit 112. The controller 111 determines that the calibration of the current sensor 115 has failed when the ratio of the deviation of the second current value to the first current value included in the specified combination is equal to or larger than a predetermined threshold. On the other hand, when the ratio is less than the predetermined threshold, the controller 111 determines that the calibration of the current sensor 115 has been successful. Note that the controller 111 may determine whether the calibration of the current sensor 115 has failed by another method such as a method using the slope, intercept, or the like of the calculated correction formula.

When determining that the calibration of the current sensor 115 has failed by the process of step S160 (step S170—YES), the controller 111 proceeds to step S190 to display information indicating that the calibration has failed in the display 124, and ends this processing routine. More specifically, in this case, the controller 111 displays a blinking pattern of light indicating the abovementioned information in the display 124 in the example embodiment.

On the other hand, when determining that the calibration of the current sensor 115 has been successful by the process of step S160 (step S170—NO), the controller 111 causes the display 124 to display information indicating that the calibration of the control circuit 11 has been successful (step S180), and ends this processing routine. More specifically, in this case, the controller 111 displays a blinking pattern of light indicating the abovementioned information in the display 124 in the example embodiment.

Note that, regarding the blinking pattern displayed on the display 124 described above, the blinking pattern indicating that the calibration of the first clock 113 has failed, the blinking pattern indicating that the calibration of the voltage sensor 114 has failed, and the blinking pattern indicating that the calibration of the current sensor 115 has failed may be different from one another. Accordingly, the control circuit 11 can notify which of the first clock 113, the voltage sensor 114, and the current sensor 115 has failed in calibration.

Further, in the processing routine of the flowchart described above, step S120, step S140, and step S160 may be executed in an order different from the order shown in FIG. 2, or may be executed in parallel. However, even in these cases, the process of step S130 is executed after the process of step S120 is performed. Further, even in these cases, the process of step S150 is executed after the process of step S140 is performed. Moreover, even in these cases, the process of step S170 is executed after the process of step S160 is performed.

The process performed by the control circuit 11 for correcting the first clock frequency will be described below with reference to FIG. 7. FIG. 7 is a diagram showing an example of a processing routine of the process performed by the control circuit 11 for correcting the first clock frequency. When performing the process using the first clock frequency of the first clock signal, the controller 111 performs the processing routine of the flowchart shown in FIG. 7, and executes the process using the corrected first clock frequency.

The controller 111 reads the first correction coefficient information stored in the storage unit 112 in advance from the storage unit 112 (step S210).

Next, the controller 111 calculates, as the corrected first clock frequency, a value obtained by multiplying the first clock frequency of the first clock signal by the first correction coefficient indicated by the first correction coefficient information read in step S210 (step S220), and ends the processing routine.

As described above, the controller 111 corrects the first clock frequency. Thus, the controller 111 can improve the accuracy of control performed using the first clock frequency.

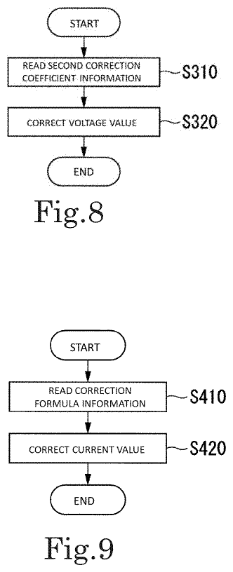

A process performed by the control circuit 11 for correcting a voltage value of a voltage detected by the voltage sensor 114 will be described below with reference to FIG. 8. FIG. 8 is a diagram showing an example of a processing routine of the process performed by the control circuit 11 for correcting a voltage value of a voltage detected by the voltage sensor 114. When performing the process using the voltage value of the voltage detected by the voltage sensor 114, the controller 111 performs the processing routine of the flowchart shown in FIG. 8, and executes the process using the corrected voltage value.

The controller 111 reads the second correction coefficient information stored in the storage unit 112 in advance from the storage unit 112 (step S310).

Next, the controller 111 calculates, as the corrected voltage value, a value obtained by multiplying the voltage value of the voltage detected by the voltage sensor 114 by the second correction coefficient indicated by the second correction coefficient information read in step S310 (step S320), and ends the processing routine.

As described above, the controller 111 corrects the voltage value of the voltage detected by the voltage sensor 114. Thus, the controller 111 can improve the accuracy of control performed using the voltage value of the voltage detected by the voltage sensor 114. In this example, the voltage is the power-supply voltage VM. That is, in this example, the controller 111 can improve the accuracy of control performed using the voltage value of the power-supply voltage VM detected by the voltage sensor 114.

A process performed by the control circuit 11 for correcting a current value of a current detected by the current sensor 115 will be described below with reference to FIG. 9. FIG. 9 is a diagram showing an example of a processing routine of the process performed by the control circuit 11 for correcting a current value of a current detected by the current sensor 115. When performing the process using the current value of the current detected by the current sensor 115, the controller 111 performs the processing routine of the flowchart shown in FIG. 9, and executes the process using the corrected current value.

The controller 111 reads the correction formula information stored in the storage unit 112 in advance from the storage unit 112 (step S410).

Next, the controller 111 calculates a value obtained by multiplying the current value of the current detected by the current sensor 115 by the slope of the correction formula indicated by the correction formula information read in step S410. The controller 111 calculates a value obtained by adding the intercept of the correction formula to the calculated value as the corrected current value (step S420), and ends the processing routine.

As described above, the controller 111 corrects the current value of the current detected by the current sensor 115. Thus, the controller 111 can improve the accuracy of control performed using the current value of the current detected by the current sensor 115.

A reduction in error in the rotation speed of the motor M driven by the calibrated control circuit 11 will be described below.

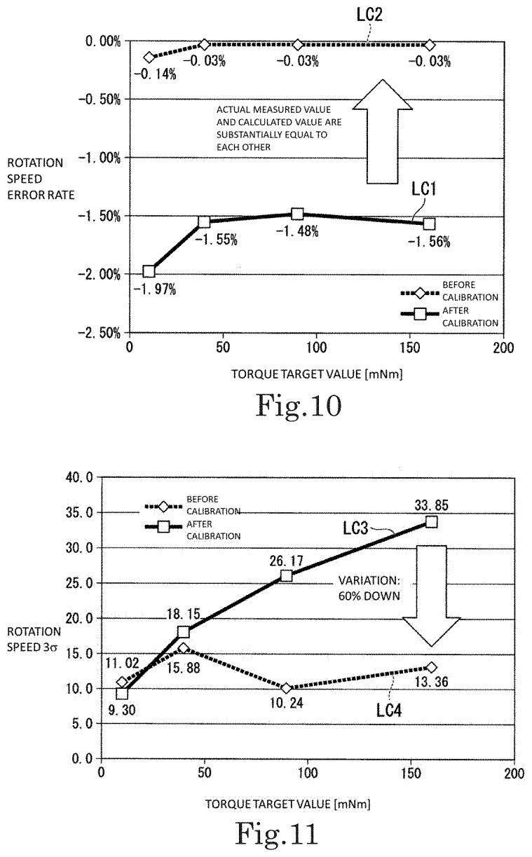

FIG. 10 is a diagram showing an example of the relationship between a torque target value of the motor M and a rotation speed error rate. Here, the torque target value of the motor M is a target value to which the torque of the motor M is brought closer by feedback control of the controller 111. The rotation speed error rate is a value defined by following Equation (12).

(Rotation speed error rate)=((Calculated value of rotation speed)(Actual measured value of rotation speed))/(Actual measured value of rotation speed) (12)

In Equation (12), the calculated value of the rotation speed indicates the rotation speed of the motor M calculated by the controller 111 on the basis of the first clock frequency. In Equation (12), the actual measured value of the rotation speed indicates the rotation speed of the motor M specified by the controller 111 on the basis of the value detected from a sensor that measures the rotation speed of the motor M. That is, the rotation speed error rate indicates a ratio of a deviation between the actual measured value of the rotation speed and the calculated value of the rotation speed to the actual measured value of the rotation speed.

The horizontal axis of the graph shown in FIG. 10 indicates the torque target value. The vertical axis of the graph indicates the rotation speed error rate.

A line LC1 in the graph shown in FIG. 10 indicates a relationship between a plurality of torque target values and a rotation speed error rate when the motor M is controlled by the control circuit 11 which is not subjected to calibration. Each plot on the line LC1 indicates an average value when the relationship is measured for a plurality of control circuits 11. In this case, the same motor M is used. It can be seen from FIG. 10 that, in this case, the rotation speed error rate assumes a value included in a range of about −1.4% to −2.0% over the entire range of the changed torque target values.

On the other hand, a line LC2 in the graph shown in FIG. 10 indicates the relationship between a plurality of torque target values and a rotation speed error rate when the motor M is controlled by the calibrated control circuit 11. Each plot on the line LC2 indicates an average value when the relationship is measured for a plurality of control circuits 11. It can be seen from FIG. 10 that, in this case, the rotation speed error rate is substantially zero over the entire range of the changed torque target values. This indicates that the calibrated control circuit 11 can rotate the motor M at a desired rotation speed regardless of the magnitude of the torque target value. In other words, this indicates that the manufacturer of control circuits 11 can reduce individual differences in controlling the rotation speed of the motor M among control circuits 11 by calibrating each of the manufactured control circuits 11 in the manner described above.

Meanwhile, FIG. 11 is a diagram showing an example of a relationship between a torque target value of the motor M and a variation in rotation speed. Here, in FIG. 11, the variation in rotation speed is indicated by a value three times the standard deviation of the rotation speed when the driving of the motor M is controlled by each of the plurality of control circuits 11. In this case, the same motor M is used.

The horizontal axis of the graph shown in FIG. 11 indicates the torque target value. The vertical axis of the graph indicates a value three times the standard deviation of the rotation speed. In the following, for convenience of description, a value that is three times the standard deviation of the rotation speed will be referred to as a rotation speed 3σ, as shown in FIG. 11.

A line LC3 in the graph shown in FIG. 11 indicates a relationship between a plurality of torque target values and the rotation speed 3σ when the motor M is controlled by each of the control circuits 11 which are not subjected to calibration. In this case, the same motor M is used. It can be seen from FIG. 11 that, in this case, the rotation speed 3σ increases with an increase in the torque target value. This indicates that individual differences are great among control circuits 11 which are not subjected to calibration, and the individual differences increase with an increase in the torque target value.

In contrast, a line LC4 in the graph shown in FIG. 11 indicates a relationship between a plurality of torque target values and the rotation speed 3σ when the motor M is controlled by each of the calibrated control circuits 11. It can be seen from FIG. 11 that, in this case, there is little change in the rotation speed 3σ over the entire range of the changed torque target values. Further, in this case, the rotation speed 3σ is smaller than the rotation speed 3σ when the motor M is controlled by each of the control circuits 11 which are not subjected to calibration over almost the entire range of the changed torque target values. This indicates that individual differences among the calibrated control circuits 11 are reduced. In other words, this indicates that the manufacturer of control circuits 11 can reduce individual differences in controlling the rotation speed of the motor M among control circuits 11 by calibrating each of the manufactured control circuits 11 in the manner described above.

A reduction in detection error of the power-supply voltage VM of the calibrated control circuit 11 will be described below.

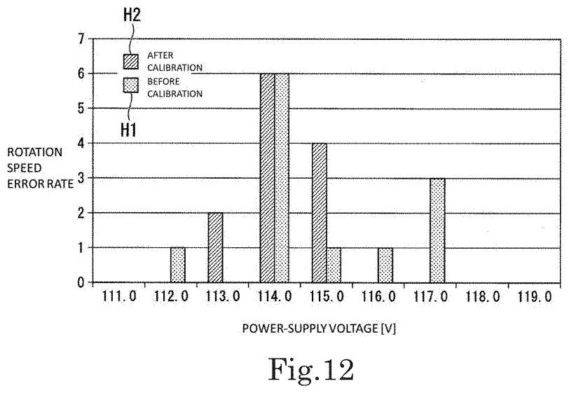

FIG. 12 is a diagram showing an example of a histogram representing a relationship between a voltage value of a voltage detected when the power-supply voltage VM is detected by a plurality of control circuits 11 and the number of control circuits 11 that have detected each of the voltage values. The vertical axis of the histogram shown in FIG. 12 indicates the number of control circuits 11. The horizontal axis of the histogram indicates the voltage value detected by the voltage sensor 114 during detection of the power-supply voltage VM. A hatching H1 shown in FIG. 12 indicates a histogram for control circuits 11 that are not subjected to calibration. A hatching H2 shown in FIG. 12 indicates a histogram for calibrated control circuits 11.

It can be seen from FIG. 12 that the plurality of control circuits 11 has a smaller variation in the detected voltage value (in other words, a smaller variance in the voltage value) after they are calibrated than before they are calibrated. That is, this indicates that the manufacturer of control circuits 11 can reduce individual differences in detecting the power-supply voltage VM by the control circuits 11 among the control circuits 11 by calibrating each of the manufactured control circuits 11 in the manner described above.

A reduction in detection error of the bus current by the calibrated control circuit 11 will be described below.

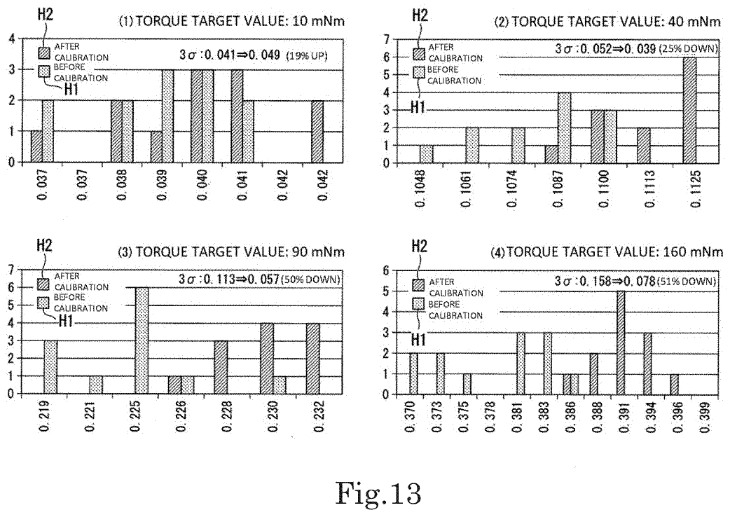

FIG. 13 is a diagram showing, when a bus current is detected by a plurality of control circuits 11, a histogram indicating a relationship between the current value of the detected current and the number of control circuits 11 that have detected each current value. FIG. 13 shows histograms for the respective four torque target values. Part (1) shown in FIG. 13 shows the histogram when the torque target value is set to 10 mNm. Part (2) shown in FIG. 13 shows the histogram when the torque target value is set to 40 mNm. Part (3) shown in FIG. 13 shows the histogram when the torque target value is set to 90 mNm. Part (4) shown in FIG. 13 shows the histogram when the torque target value is set to 160 mNm.

A hatching H1 shown in FIG. 13 indicates a histogram for control circuits 11 that are not subjected to calibration, as in FIG. 12. A hatching H2 shown in FIG. 13 indicates a histogram for calibrated control circuits 11, as in FIG. 12.

It can be seen from FIG. 13 that, as the torque target value increases, the plurality of control circuits 11 has a smaller variation in the detected current value (in other words, a smaller variance in the current value) after they are calibrated than before they are calibrated. That is, this indicates that the manufacturer of control circuits 11 can reduce individual differences in detection of the bus current among the control circuits 11 by calibrating each of the manufactured control circuits 11 in the manner described above.

A reduction in variation in the rotation speed of the motor M controlled by the control circuit 11 and a reduction in variation in air volume will be described below.

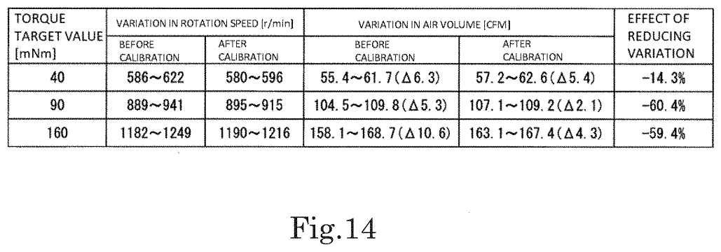

FIG. 14 is a diagram showing a variation in rotation speed of the motor M and a variation in air volume due to differences in control circuits 11, when each of the plurality of control circuits 11 controls the same motor M.

It can be seen from FIG. 14 that the variation in rotation speed of the motor M due to differences among control circuits 11 when each of the plurality of control circuits 11 controls the same motor M is smaller after calibration is performed than before calibration is performed. For example, when the torque target value is 40 mNm, the rotation speed varies within a range of 586 rpm to 622 rpm before calibration is performed. On the other hand, the rotation speed in this case varies within a range of 580 rpm to 596 rpm after the calibration is performed. That is, the variation in this case is smaller after the calibration is performed than before the calibration is performed. This tendency also appears when the torque target value is 90 mNm and the torque target value is 160 mNm. Further, the rate of the reduction in the variation is greater when the torque target value is 90 mNm or more than when the torque target value is 40 mNm.

Further, it can be seen from FIG. 14 that the variation in air volume of a fan F due to differences among control circuits 11 when each of the plurality of control circuits 11 controls the same motor M is smaller after calibration is performed than before calibration is performed. For example, when the torque target value is 40 mNm, the air volume varies within a range of 55.4 CFM to 61.7 CFM before calibration is performed. On the other hand, the air volume in this case varies within a range of 57.4 CFM to 62.6 CFM after the calibration is performed. That is, the variation in this case is smaller after the calibration is performed than before the calibration is performed. This tendency also appears when the torque target value is 90 mNm and the torque target value is 160 mNm. Further, as the torque target value increases, the rate of reduction in the variation increases.

It can be seen from the above that the calibration of control circuits 11 described in the example embodiment reduces individual differences among the manufactured control circuits 11. That is, the control circuit 11 enables reduction in individual differences, while suppressing an increase in manufacturing cost.

In addition, the calibration circuit 12 includes a part of a circuit necessary for calibrating the control circuit 11, and the controller 111 has a function of controlling the calibration circuit 12, whereby the circuit configuration of each of the control circuit 11 and the calibration circuit 12 can be simplified. This also leads to a reduction in the manufacturing cost of the control circuit 11.

The control circuit 11 described above may be configured not to control the driving of the motor M before the control circuit 11 is calibrated. That is, the controller 111 may be configured not to start driving the motor M, even when receiving an operation to start driving the motor M after the control circuit 11 is connected to the motor M. For example, after receiving the operation, the controller 111 determines whether or not the calibration has been performed. When determining that the calibration has been performed, the controller 111 starts driving the motor M. On the other hand, when determining that the calibration has not been performed, the controller 111 does not start driving the motor M. This can prevent the control circuit 11 which is not subjected to calibration from being used to control the driving of the motor M.

The controller 111 performs the determination described above in such a way that, when the controller 111 has been successful in calibrating the control circuit 11, the controller 111 stores information indicating that the calibration has been successful in the storage unit 112. Note that the controller 111 may perform the determination by another method.

As described above, the control device (the control circuit 11 in the example described above) according to the example embodiment is a control circuit that controls a target device (the motor M in the example described above), the control circuit including a controller (the controller 111 in the example described above) that controls a calibration circuit (the calibration circuit 12 in the example described above) to be connected to the control circuit, in which the controller calibrates the control circuit by controlling the calibration circuit, when a predetermined condition (the calibration start condition in the example described above) is satisfied in a state (the connection state in the example described above) where the control circuit is connected to the calibration circuit. Thus, the control circuit enables reduction in individual differences, while suppressing an increase in manufacturing cost.

Further, the control circuit may include a first clock (the first clock 113 in the example described above) that generates a first clock signal having a predetermined first clock frequency, in which the calibration of the control circuit may include calibration of the first clock, the calibration circuit may include a second clock (the second clock 121C) that generates a second clock signal having a predetermined second clock frequency, and when the predetermined condition is satisfied in a state where the control circuit is connected to the calibration circuit, the controller may acquire the second clock signal from the second clock, and calibrate the first clock on the basis of the acquired second clock signal.

Further, in the control circuit, the controller may calculate, as a first actual measured value, a number-of-clock-pulse counted value of the first clock signal per one cycle of the second clock signal acquired from the second clock, specify, as a first nominal value, a number-of-clock-pulse counted value of the first clock signal per one cycle of the second clock signal when the clock frequency of the first clock signal matches the first clock frequency, calculate, as a first correction coefficient, a value obtained by dividing the calculated first actual measured value by the specified first nominal value, and calibrate the first clock on the basis of the calculated first correction coefficient.

Further, the control circuit may include a voltage sensor (the voltage sensor 114 in the example described above), in which the voltage sensor may include a first voltage divider circuit (the voltage divider circuit included in the voltage sensor 114 in the example described above) that divides a supplied voltage (the power-supply voltage VM, the power-supply voltage VDD in the example described above), the calibration of the control circuit may include calibration of the voltage sensor, the calibration circuit may include: a DC power circuit (the DC power circuit 125 in the example described above) that generates a voltage to be used as a reference as a reference voltage (the power-supply voltage VDD in the example described above), and outputs the generated reference voltage to the voltage sensor; a second voltage divider circuit (the voltage divider circuit VD1 in the example described above) that has a structure same as the structure of the first voltage divider circuit, has a resistor having a tolerance smaller than a tolerance of a resistor of the first voltage divider circuit, and divides the reference voltage; and an output voltage generation circuit (the combination of the instrumentation amplifier A1 and the voltage follower A2 in the example described above) that generates, as an output voltage, a voltage according to a difference between a first detection voltage after the second voltage divider circuit divides the reference voltage and a second detection voltage after the first voltage divider circuit divides the reference voltage, and the controller may calculate a second correction coefficient (the second correction coefficient HC2 in the example described above) on the basis of the output voltage generated by the output voltage generation circuit and calibrate the voltage sensor on the basis of the calculated second correction coefficient.

Further, the control circuit may include a current sensor (the current sensor 115 in the example described above), in which the calibration of the control circuit may include calibration of the current sensor, the calibration circuit may output a plurality of currents (four currents in the example described above) having different current values to the current sensor in accordance with control by the controller when the predetermined condition is satisfied in a state where the control circuit is connected to the calibration circuit, the current sensor may detect each of the plurality of currents that has been acquired, and the controller may calibrate the current sensor on the basis of the detection result of each of the plurality of currents by the current sensor.

In the control circuit, the controller may calculate a correction formula (regression line in the example described above) based on the detection result of each of the plurality of currents, and calibrate the current sensor on the basis of the calculated correction formula.

In the control circuit, the target device may be a motor (the motor M in the example described above).

In the control circuit, the calibration circuit may include a display (the display 124 in the example described above), and the controller may cause the display to display information regarding calibration of the control circuit.

Further, the control circuit is a control circuit that controls a device to be controlled, the control circuit including a controller that controls a calibration circuit to be connected to the control circuit, in which the controller calibrates the control circuit by controlling the calibration circuit, when a predetermined condition is satisfied in a state where the control circuit is connected to the calibration circuit, and when the controller does not calibrate the control circuit, the controller does not control the device. This can prevent the control circuit which is not subjected to calibration from controlling the device.

While the example embodiment of the present disclosure has been described above in detail with reference to the drawings, a specific configuration is not limited to the example embodiment, and various changes, substitutions, deletions, etc. may be possible without departing from the scope of the present disclosure.

Features of the above-described preferred example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A control circuit that controls a target device, the control circuit comprising:
a controller that controls a calibration circuit to be connected to the control circuit; wherein
the controller calibrates the control circuit by controlling the calibration circuit when a predetermined condition is satisfied in a state where the control circuit is connected to the calibration circuit.

2. The control circuit according to claim 1, further comprising:
a first clock that generates a first clock signal having a predetermined first clock frequency; wherein
the calibration of the control circuit includes calibration of the first clock;
the calibration circuit includes a second clock that generates a second clock signal having a predetermined second clock frequency; and
when the predetermined condition is satisfied in a state where the control circuit is connected to the calibration circuit, the controller acquires the second clock signal from the second clock, and calibrates the first clock based on the acquired second clock signal.

3. The control circuit according to claim 2, wherein the controller:
calculates, as a first actual measured value, a number-of-clock-pulse counted value of the first clock signal per one cycle of the second clock signal acquired from the second clock;
specifies, as a first nominal value, a number-of-clock-pulse counted value of the first clock signal per one cycle of the second clock signal when the clock frequency of the first clock signal matches the first clock frequency;
calculates, as a first correction coefficient, a value obtained by dividing the calculated first actual measured value by the specified first nominal value; and
calibrates the first clock based on the calculated first correction coefficient.

4. The control circuit according to claim 1, further comprising a voltage sensor; wherein
the voltage sensor includes a first voltage divider circuit that divides a supplied voltage;
the calibration of the control circuit includes calibration of the voltage sensor;
the calibration circuit includes:
a DC power circuit that generates a voltage to be used as a reference as a reference voltage, and outputs the generated reference voltage to the voltage sensor;
a second voltage divider circuit that includes a structure that is the same as the structure of the first voltage divider circuit, includes a resistor having a tolerance smaller than a tolerance of a resistor of the first voltage divider circuit, and divides the reference voltage; and
an output voltage generation circuit that generates, as an output voltage, a voltage according to a difference between a first detection voltage after the second voltage divider circuit divides the reference voltage and a second detection voltage after the first voltage divider circuit divides the reference voltage; and
the controller calculates a second correction coefficient based on the output voltage generated by the output voltage generation circuit and calibrates the voltage sensor based on the calculated second correction coefficient.

5. The control circuit according to claim 1, further comprising a current sensor, wherein
the calibration of the control circuit includes calibration of the current sensor;
the calibration circuit outputs a plurality of currents having different current values to the current sensor in accordance with control by the controller when the predetermined condition is satisfied in a state where the control circuit is connected to the calibration circuit;
the current sensor detects each of the plurality of currents that has been acquired; and
the controller calibrates the current sensor based on the detection result of each of the plurality of currents by the current sensor.

6. The control circuit according to claim 5, wherein the controller calculates a correction formula based on the detection result of each of the plurality of currents, and calibrates the current sensor based on the calculated correction formula.

7. The control circuit according claim 1, wherein the target device is a motor.

8. The control circuit according to claim 1, wherein
the calibration circuit includes a display; and
the controller causes the display to display information regarding calibration of the control circuit.

9. A control circuit that controls a device to be controlled, the control circuit comprising:
a controller that controls a calibration circuit to be connected to the control circuit; wherein
the controller calibrates the control circuit by controlling the calibration circuit, when a predetermined condition is satisfied in a state where the control circuit is connected to the calibration circuit; and
the controller does not control the device when the controller does not calibrate the control circuit.

10. A calibration system comprising:
the control circuit according to claim 1; and
the calibration circuit.

11. The control circuit according to claim 2, further comprising:
a voltage sensor; wherein
the voltage sensor includes a first voltage divider circuit that divides a supplied voltage;
the calibration of the control circuit includes calibration of the voltage sensor;
the calibration circuit includes:
a DC power circuit that generates a voltage to be used as a reference as a reference voltage, and outputs the generated reference voltage to the voltage sensor;
a second voltage divider circuit that includes a structure the same as the structure of the first voltage divider circuit, includes a resistor having a tolerance smaller than a tolerance of a resistor of the first voltage divider circuit, and divides the reference voltage; and
an output voltage generation circuit that generates, as an output voltage, a voltage according to a difference between a first detection voltage after the second voltage divider circuit divides the reference voltage and a second detection voltage after the first voltage divider circuit divides the reference voltage; and
the controller calculates a second correction coefficient based on the output voltage generated by the output voltage generation circuit and calibrates the voltage sensor based on the calculated second correction coefficient.

12. The control circuit according to claim 3, further comprising:
a voltage sensor; wherein
the voltage sensor includes a first voltage divider circuit that divides a supplied voltage;
the calibration of the control circuit includes calibration of the voltage sensor;
the calibration circuit includes:
a DC power circuit that generates a voltage to be used as a reference as a reference voltage, and outputs the generated reference voltage to the voltage sensor;
a second voltage divider circuit that includes a structure that is the same as the structure of the first voltage divider circuit, includes a resistor having a tolerance smaller than a tolerance of a resistor of the first voltage divider circuit, and divides the reference voltage; and
an output voltage generation circuit that generates, as an output voltage, a voltage according to a difference between a first detection voltage after the second voltage divider circuit divides the reference voltage and a second detection voltage after the first voltage divider circuit divides the reference voltage; and
the controller calculates a second correction coefficient based on the output voltage generated by the output voltage generation circuit and calibrates the voltage sensor based on the calculated second correction coefficient.

13. The control circuit according to claim 2, further comprising a current sensor, wherein
the calibration of the control circuit includes calibration of the current sensor;
the calibration circuit outputs a plurality of currents having different current values to the current sensor in accordance with control by the controller when the predetermined condition is satisfied in a state where the control circuit is connected to the calibration circuit;
the current sensor detects each of the plurality of currents that has been acquired; and
the controller calibrates the current sensor based on the detection result of each of the plurality of currents by the current sensor.

14. The control circuit according to claim 3, further comprising a current sensor, wherein
the calibration of the control circuit includes calibration of the current sensor;
the calibration circuit outputs a plurality of currents having different current values to the current sensor in accordance with control by the controller when the predetermined condition is satisfied in a state where the control circuit is connected to the calibration circuit;
the current sensor detects each of the plurality of currents that has been acquired; and
the controller calibrates the current sensor based on the detection result of each of the plurality of currents by the current sensor.

15. The control circuit according to claim 4, further comprising a current sensor; wherein
the calibration of the control circuit includes calibration of the current sensor;
the calibration circuit outputs a plurality of currents having different current values to the current sensor in accordance with control by the controller when the predetermined condition is satisfied in a state where the control circuit is connected to the calibration circuit;
the current sensor detects each of the plurality of currents that has been acquired; and
the controller calibrates the current sensor based on the detection result of each of the plurality of currents by the current sensor.

16. The control circuit according claim 2, wherein the target device is a motor.

17. The control circuit according claim 3, wherein the target device is a motor.

18. The control circuit according claim 4, wherein the target device is a motor.

19. The control circuit according claim 5, wherein the target device is a motor.

20. The control circuit according claim 6, wherein the target device is a motor.
